(19) United States
(12) Patent Application Publication
(10) Pub. No.: US 2025/0113696 A1
(43) Pub. Date: Apr. 3, 2025

(54) DISPLAY SUBSTRATE, DISPLAY PANEL, AND PREPARATION METHODS THEREOF

(71) Applicant: Chengdu Vistar Optoelectronics Co., Ltd., Chengdu (CN)

(72) Inventors: Li HE, Chengdu (CN); Xiuqi HUANG, Chengdu (CN); Xuan CAO, Chengdu (CN); Yunlei CHEN, Chengdu (CN); Xiaolong ZHANG, Chengdu (CN)

(73) Assignee: Chengdu Vistar Optoelectronics Co., Ltd., Chengdu (CN)

(21) Appl. No.: 18/975,495

(22) Filed: Dec. 10, 2024

(30) Foreign Application Priority Data
Dec. 15, 2023 (CN) 202311742917.4

(51) Int. Cl. H10H 29/85; H10H 29/01; H10H 29/80

(52) U.S. Cl. CPC H10H 29/857; H10H 29/034; H10H 29/0364; H10H 29/842

(57) ABSTRACT

A display substrate, a display panel, and preparation methods thereof. The display substrate includes a base substrate, a bonding pad, and an insulating layer. The bonding pad is located on one side of the base substrate and includes at least two bonding pad layers stacked in a thickness direction of the base substrate. The insulating layer is located between adjacent two of the bonding pad layers, and the insulating layer includes a via. In adjacent two of the bonding pad layers, the bonding pad layer on the side away from the base substrate extends into the via and is electrically connected to the bonding pad layer on the side close to the base substrate.

### CROSS-REFERENCE TO RELATED APPLICATIONS

This application claims priority to Chinese Patent Application No. 202311742917.4, titled “DISPLAY SUBSTRATE, DISPLAY PANEL, AND PREPARATION METHODS THEREOF” and filed on Dec. 15, 2023, which is hereby incorporated by reference in its entirety.

### TECHNICAL FIELD

The present application belongs to the field of display technology, and in particular, relates to a display substrate, a display panel, and preparation methods thereof.

### BACKGROUND

With the development of display technology, the performance requirements for display devices are getting higher and higher. Micro-LED display technology has gradually become the mainstream product of the next generation of display with its low power consumption, long service life, and high brightness. However, the performance of existing Micro-LED display substrates still needs to be improved.

### SUMMARY

Embodiments of the present application provide a display substrate, a display panel, and preparation methods thereof, which can improve the reliability of connection between a welding portion and a bonding pad, and improve the phenomenon that the two are separated due to the complete alloying and exhaustion of metal elements in the bonding pad.

An embodiment in a first aspect of the present application provides a display substrate, including:
a base substrate;
a bonding pad located on a side of the base substrate and including at least two bonding pad layers stacked in a thickness direction of the base substrate; and
at least one insulating layer located between adjacent two of the bonding pad layers, the insulating layer comprising a via, and in adjacent two of the bonding pad layers, the bonding pad layer on a side away from the base substrate extending into the via and being electrically connected to the bonding pad layer on a side close to the base substrate.

An embodiment in a second aspect of the present application further provides a method for preparing a display substrate, including:
providing a base substrate;
forming a bonding pad layer on a side of the base substrate;
forming an insulating layer on a side of the bonding pad layer away from the base substrate, the insulating layer including a via; and
forming another bonding pad layer on a side of the insulating layer away from the base substrate, where in the two bonding pad layers, the bonding pad layer on a side away from the base substrate extends into the via and is electrically connected to the bonding pad layer on a side close to the base substrate.

An embodiment in a third aspect of the present application further provides a display panel, including any one of the display substrates provided in the first aspect of the present application, a light-emitting device, and a welding portion, wherein the welding portion is located in the via and is electrically connected to the bonding pad, and the light-emitting device is located on a side of the welding portion away from the bonding pad and is electrically connected to the welding portion.

An embodiment in a fourth aspect of the present application further provides a method for preparing a display panel, including:
preparing the display substrate according to the preparation method as described in the second aspect;
forming a welding material layer located on a side surface of the mask layer away from the base substrate, wherein an orthographic projection of the welding material layer on the base substrate and an orthographic projection of the via on the base substrate at least partially overlap;
removing the mask layer to synchronously remove a part of the welding material layer, retaining part of the welding material layer located within the first opening to form a welding portion, wherein the welding portion is electrically connected to the bonding pad; and
electrically connecting a light-emitting device to the welding portion.

The display substrate provided by the present application includes a base substrate, a bonding pad, and an insulating layer, wherein the bonding pad is located on a side surface of the base substrate, and one or more bonding pads are provided to achieve electrical connection between a light-emitting device and a circuit inside the base substrate, thereby achieving light-emitting display. The bonding pad includes at least two bonding pad layers stacked in the thickness direction of the base substrate, which can increase the thickness of the bonding pad in the thickness direction of the base substrate, increase the volume of the bonding pad, and increase the amount of the material used in the bonding pad to prevent excessive migration of metal elements from the bonding pad to a welding portion during the process of the electrical connection and alloying between the bonding pad and the welding portion, thereby ensuring that sufficient metal elements still remain in the bonding pad, preventing the bonding pad from being completely alloyed and exhausted after the metal elements migrate due to too little material used for the bonding pad, improving the reliability of connection between the welding portion and the bonding pad, and improving the phenomenon that the two are separated due to the complete alloying and exhaustion of metal elements in the bonding pad. On the one hand, the insulating layer achieves an effect of insulation to prevent short circuit between the adjacent bonding pads. On the other hand, the insulating layer is disposed between the adjacent bonding pad layers, the bonding pad layer on the side away from the base substrate extends along the inner wall of the via and is electrically connected to the bonding pad layer on the side close to the base substrate, so that part of the bonding pad layer located on the side away from the base substrate is located on the side of the insulating layer away from the base substrate, thereby achieving the effect of heightening a part of region of the bonding pad layer on the side away from the base substrate through the insulating layer, and so that the light-emitting device that is subsequently electrically connected to the bonding pad can be higher than the non-bonding pad region to form a step difference, which is conducive to reducing the probability of displaying dark spots caused by the black matrix covering the light-emitting device when the display panel is packaged subsequently. Simultaneously, the insulating layer can further improve the adhesion between the adjacent bonding pad layers, improve the anti-falling property between the adjacent bonding pad layers, and increase the firmness between the adjacent bonding pad layers, so as to improve the yield of the display substrate.

### BRIEF DESCRIPTION OF THE DRAWINGS

In order to illustrate the technical solutions in the embodiments of the present application more clearly, the drawings to be used in the embodiments of the present application will be briefly described below, apparently, the drawings described below are merely some embodiments of the present application, those skilled in this field can obtain other drawings based on these drawings without paying creative work.

FIG. 1 is a cross-sectional view of a display substrate provided in an embodiment of the present application;

FIG. 2 is a cross-sectional view of another display substrate provided in an embodiment of the present application;

FIG. 3 is a cross-sectional view of another display substrate provided in an embodiment of the present application;

FIG. 4 is a cross-sectional view of another display substrate provided in an embodiment of the present application;

FIG. 5 is a cross-sectional view of another display substrate provided in an embodiment of the present application;

FIG. 6 is a cross-sectional view of another display substrate provided in an embodiment of the present application;

FIG. 7 is a flowchart of a method for preparing a display substrate provided in an embodiment of the present application;

FIG. 8 is a cross-sectional view of a display panel provided in an embodiment of the present application;

FIG. 9 to FIG. 14 are schematic diagrams of film layer changes during a process of preparing a display substrate provided in an embodiment of the present application; and

FIG. 15 and FIG. 16 are schematic diagrams of film layer changes during the process of preparing the display panel provided in an embodiment of the present application.

### REFERENCE NUMBERS

1—display substrate; 10—base substrate; 11—bonding pad; 110—bonding pad layer; 111—first bonding pad layer; 112—second bonding pad layer; 12—protective layer; 121—first opening; 13—insulating layer; 131—via; 14—heightening layer; 141—opening; H—isolation gap; 2—light-emitting device; 3—welding portion; 4—protective material layer; 5—mask layer; 51—second opening; 6—welding material layer.

### DETAILED DESCRIPTION

The features and exemplary embodiments of various aspects in the present application will be described in detail below. In the following detailed description, many specific details are proposed in order to provide a comprehensive understanding of the present application. However, it is obvious to those skilled in the art that the present application may be implemented without some of these specific details. The following description of the embodiments is only to provide a better understanding of the present application by illustrating examples of the present application.

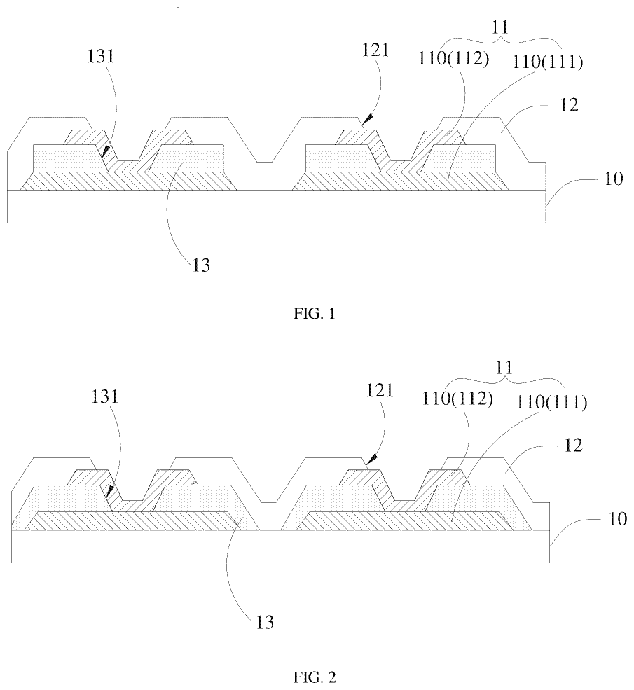

In order to better understand the present application, a display substrate and a preparation method thereof according to the embodiments of the present application are described in detail below with reference to FIG. 1 to FIG. 16.

Referring to FIG. 1, an embodiment of the present application provides a display substrate, including a base substrate 10, a bonding pad 11, and at least one insulating layer 13. The bonding pad 11 is located on one side of the base substrate 10 and includes at least two bonding pad layers stacked in a thickness direction of the base substrate 10. The insulating layer 13 is located between adjacent two of the bonding pad layers, the insulating layer 13 includes a via 131, and in adjacent two of the bonding pad layers, the bonding pad layer on the side away from the base substrate 10 extends into the via 131 and is electrically connected to the bonding pad layer on the side close to the base substrate 10.

The display substrate provided by the present application includes a base substrate 10, a bonding pad 11, and an insulating layer 13, wherein the bonding pad 11 is located on one side surface of the base substrate 10, and one or more bonding pads are provided to achieve the electrical connection between a light-emitting device 41 and a circuit inside the base substrate 10, thereby achieving the light-emitting display. The bonding pad 11 includes at least two bonding pad layers stacked in the thickness direction of the base substrate 10, which can increase the thickness of the bonding pad 11 in the thickness direction of the base substrate 10, increase the volume of the bonding pad 11, and increase the amount of the material used in the bonding pad 11 to prevent excessive migration of metal elements from the bonding pad 11 to a welding portion 3 during the process of electrical connection and alloying between the bonding pad 11 and the welding portion 3, thereby ensuring that sufficient metal elements still remain in the bonding pad 11, preventing the bonding pad 11 from being completely alloyed and exhausted after the metal elements migrate due to too little material used for the bonding pad 11, improving the reliability of connection between the welding portion 3 and the bonding pad 11, and improving the phenomenon that the two are separated due to the complete alloying and exhaustion of metal elements in the bonding pad 11. On the one hand, the insulating layer 13 achieves an effect of insulation to prevent short circuit between the adjacent bonding pads 11. On the other hand, the insulating layer 13 is disposed between the adjacent bonding pad layers, the bonding pad layer on the side away from the base substrate 10 extends along an inner wall of the via 131 and is electrically connected to the bonding pad layer on the side close to the base substrate 10, so that part of the bonding pad layer located on the side away from the base substrate 10 is located on the side of the insulating layer 13 away from the base substrate 10, thereby achieving the effect of heightening a part of region of the bonding pad layer on the side away from the base substrate 10 through the insulating layer 13, so that the light-emitting device that is subsequently electrically connected to the bonding pad 11 can be higher than a maximum height of a non-bonding pad region in the display panel to form a step difference, which is conducive to reducing the probability of displaying dark spots caused by the black matrix covering the light-emitting device 41 when the display panel is packaged subsequently. Simultaneously, the insulating layer 13 can further improve the adhesion between the adjacent bonding pad layers, improve the anti-falling property between the adjacent bonding pad layers, and increase the firmness between the adjacent bonding pad layers, so as to improve the yield of the display substrate.

It should be noted that the bonding pad 11 includes but is not limited to two bonding pad layers, and may include three or more layers. The present application only takes an example of the bonding pad 11 including two bonding pad layers for illustration.

Specifically, the light-emitting device 41 may include Micro-LED, LED, etc., which are not specially limited in the present application.

In a feasible implementation, as shown in FIG. 1, the bonding pad 11 includes a first bonding pad layer 111 and a second bonding pad layer 112 stacked in the thickness direction away from the base substrate 10, the insulating layer 13 is located between the first bonding pad layer 111 and the second bonding pad layer 112, an orthographic projection of the via 131 on the base substrate 10 is located within an orthographic projection of the first bonding pad layer 111 on the base substrate 10, and the second bonding pad layer 112 extends along the inner wall of the via 131 and is electrically connected to the first bonding pad layer 111.

In the above implementation, the area of the orthographic projection of the via 131 on the base substrate 10 is smaller than the area of the orthographic projection of the first bonding pad layer 111 on the base substrate 10, which can ensure that the insulating layer 13 has a good effect of heightening the bonding pad layer located on the side away from the base substrate 10.

Specifically, the second bonding pad layer 112 extends along the inner wall of the via 131 and is electrically connected to the first bonding pad layer 111, the second bonding pad layer 112 can cover part or all of the first bonding pad layer 111 exposed by the via 131, which are not specially limited by the present application. As an optional method, the second bonding pad layer 112 extends along the inner wall of the via 131 and completely covers all of the first bonding pad layer 111 exposed by the via 131. In this case, the contact area between the second bonding pad layer 112 and the first bonding pad layer 111 is larger, making the connection between the second bonding pad layer 112 and the first bonding pad layer 111 more stable to further improve the reliability of the display substrate.

In a feasible implementation, the first bonding pad layer 111 and the second bonding pad layer 112 are made of the same material, using the same material can improve the difference in electrical signal transmission between the first bonding pad layer 111 and the second bonding pad layer 112, improve the reliability of electrical signal transmission, and increase the overall content of metal elements in the bonding pad.

In a feasible implementation, the material of the bonding pad 11 (including the first bonding pad layer and the second bonding pad layer) includes at least one of copper, titanium, molybdenum, and niobium. Specifically, the bonding pad 11 may include copper and titanium, or copper, molybdenum and niobium, or molybdenum and copper, or a stacked arrangement of titanium, copper and titanium, etc. Specifically, the material of the bonding pad 11 may be a metal that is easily to form an alloy, so as to facilitate welding, thereby improving the yield of electrical connection.

In a feasible implementation, as shown in FIG. 2, the insulating layer 13 on the side close to the base substrate extends and covers a peripheral side of the bonding pad layer on the side close to the base substrate. Specifically, the insulating layer 13 extends along the first bonding pad layer 111 and covers the peripheral side of the first bonding pad layer 111. In the above implementation, the insulating layer 13 extends along the first bonding pad layer 111 and covers the peripheral side of the first bonding pad layer 111, so as to protect the first bonding pad layer 111 and prevent the short circuit between the adjacent first bonding pad layers 111 due to contact, that is, achieve the insulation between the adjacent first bonding pad layers 111.

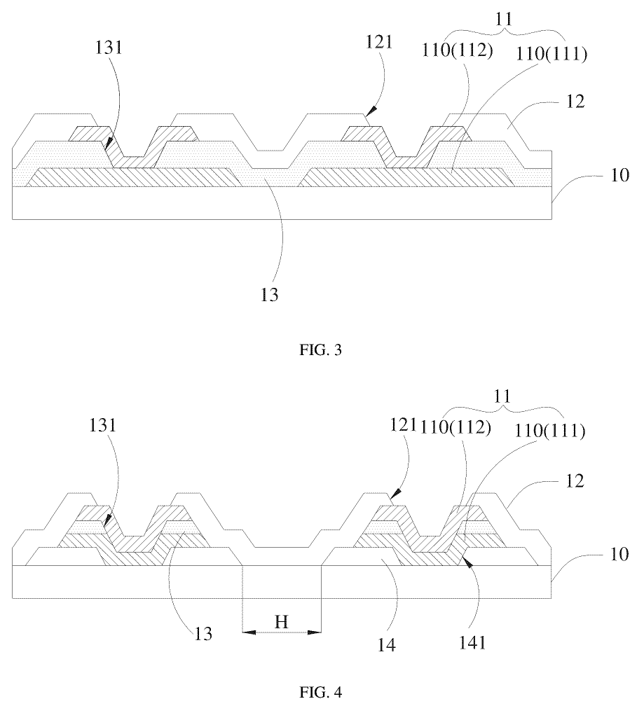

In the above implementation, as shown in FIG. 1 and FIG. 2, the insulating layers 13 each in the adjacent bonding pads are spaced apart from one another, or as shown in FIG. 3, the insulating layer 13 extends to abut against the base substrate 10, and the insulating layers 13 in the adjacent bonding pads are continuously disposed.

As shown in FIG. 1 and FIG. 2, when the insulating layers 13 each in the adjacent bonding pads 11 are spaced apart from one another, part of the base substrate 10 located between the adjacent bonding pads 11 can be exposed, which is conducive to forming a height step difference between a bonding pad region and a non-bonding pad region, thereby increasing a maximum height difference between the light-emitting device 2 and the non-bonding pad region in the display panel after the light-emitting device 2 is subsequently electrically connected to the bonding pad 11, so as to reduce the probability of displaying dark spots caused by the black matrix covering the light-emitting device 2 when the display panel is packaged subsequently.

As shown in FIG. 3, when the insulating layer 13 extends to abut against the base substrate 10 and the insulating layers 13 in the adjacent bonding pads are continuously disposed, the insulating layers 13 extend to the base substrate 10 and are continuously disposed, the insulating layer 13 can achieve relatively closed protection for the part between the adjacent first bonding pad layers 111, which can further reduce the probability of the first bonding pad layer 111 contacting water and oxygen.

In a feasible implementation, the insulating layer 13 includes an organic material layer or an inorganic material layer, or the insulating layer 13 includes an organic material layer and an inorganic material layer alternately disposed in the thickness direction of the base substrate 10. The inorganic material may include at least one of silicon nitride, silicon oxide, and silicon oxynitride. On the one hand, the functions of insulation and protection can be realized, and on the other hand, the adhesion between the first bonding pad layer 111 and the second bonding pad layer 112 can be improved.

Specifically, the insulating layer 13 has a thickness of 2 μm to 3 μm, so that the insulating layer 13 can play the effect of heightening the second bonding pad layer 112, thereby increasing the maximum height difference between the light-emitting device 2 and the non-bonding pad region in the display panel after the light-emitting device 2 is subsequently electrically connected to the bonding pad 11, so as to reduce the probability of displaying dark spots caused by the black matrix covering the light-emitting device 2 when the display panel is packaged subsequently. The thickness of the insulating layer 13 may be 2 μm, 2.1 μm, 2.3 μm, 2.5 μm, 2.6 μm, 2.8 μm, 3 μm, or the like.

In a feasible implementation, as shown in FIG. 1 to FIG. 3, the display backplane further includes a protective layer 12 at least partially located on the side surface of the bonding pad 11 away from the base substrate 10 and including at least one first opening 121, and the orthographic projection of the first opening 121 on the base substrate 10 is located within the orthographic projection of the bonding pad 11 on the base substrate 10.

The protective layer 12 is at least partially located on the side surface of the bonding pad 11 away from the base substrate 10 and includes at least one first opening 121, which can shield and protect a part of the side surface of the bonding pad 11 away from the base substrate 10, so as to ensure the performance of the bonding pad 11, improve the phenomenon of oxidation of the bonding pad due to exposure, reduce the probability of corrosion of the bonding pad in contact with corrosive materials in the subsequent preparation process, thereby improving the electrical connection stability of the bonding pad. Simultaneously, exposing the part of the side surface of the bonding pad 11 away from the base substrate 10 through the first opening 121 facilitates the arrangement of the welding portion 3, thereby achieving electrical connection between the light-emitting device 2 and the bonding pad 11.

In the above implementation, the protective layers 12 each between the adjacent bonding pads 11 may be connected with or spaced apart from one another.

In the above implementation, as shown in FIG. 3, the protective layer 12 extends along the bonding pad 11 and covers the peripheral side of the bonding pad 11. On the one hand, the bonding pad 11 can be protected, and on the other hand, the adjacent bonding pads 11 can be insulated.

When the bonding pad 11 includes the first bonding pad layer 111 and the second bonding pad layer 112, the protective layer 12 may extend along the second bonding pad layer 112, and the protective layer 12 simultaneously covers the peripheral sides of the first bonding pad layer 111 and the second bonding pad layer 112 to protect the peripheral sides of the first bonding pad layer 111 and the second bonding pad layer 112, thereby preventing the adjacent bonding pads 11 from short circuit due to contact, namely, achieving insulation between the adjacent bonding pads 11. When the insulating layer 13 is provided between the first bonding pad layer 111 and the second bonding pad layer 112, the protective layer 12 also covers the peripheral side of the insulating layer 13.

In a feasible implementation, the insulating layers 13 each in the adjacent bonding pads 11 are spaced apart from one another, the insulating layer 13 extends along the bonding pad layer on the side close to the base substrate and covers the peripheral side of the bonding pad layer on the side close to the base substrate, and the protective layer 12 extends to the peripheral side of the insulating layer 13.

In the above implementation, when the insulating layers 13 each are spaced apart from one another, the protective layer 12 can cover the bonding pad 11 and the peripheral side of the insulating layer 13, which can further protect the bonding pad 11 and the insulating layer 13.

In a feasible implementation, as shown in FIG. 2, the insulating layers 13 each in the adjacent bonding pads 11 are spaced apart from one another, and the protective layer 12 extends between the insulating layers 13 in the adjacent bonding pads 11 and abuts against the base substrate 10.

In the above implementation, the insulating layers 13 each are spaced apart from one another, so that the protective layer 12 is directly in contact with the base substrate 10. Due to the lack of height of the insulating layer 13, a height step difference is formed between the bonding pad region and the non-bonding pad region, thereby increasing the maximum height difference between the light-emitting device 2 and the non-bonding pad region in the display panel after the light-emitting device 2 is subsequently electrically connected to the bonding pad 11, which facilities to reduce the probability of displaying dark spots caused by the black matrix covering the light-emitting device 2 when the display panel is packaged subsequently.

In a feasible implementation, as shown in FIG. 3, the insulating layer 13 extends to abut against the base substrate 10, the insulating layers 13 in the adjacent bonding pads are continuously disposed, and the protective layer 12 extends between the adjacent bonding pads 11 and abuts against the insulating layer 13. Therefore, the part between the adjacent bonding pads 11 can be packaged through the insulating layer 13 and the protective layer 12 to reduce the probability of the water and oxygen contacting the bonding pad 11, which is conducive to improving the performance of the bonding pad 11.

In the above implementation, the material of the protective layer 12 includes an inorganic material. The inorganic material has better water and oxygen isolation performance, which can reduce the damage to the protective layer 12 in subsequent processes, so as to improve the reliability of the protective layer 12. Specifically, the inorganic material includes at least one of silicon nitride and silicon oxide. The material is easy to obtain and has good insulation and water and oxygen isolation capabilities.

In the above implementation, the protective layer 12 has a thickness of 0.1 μm to 0.3 μm. Specifically, in the thickness direction of the base substrate 10, the thickness of the protective layer 12 is lower than the minimum thickness of the bonding pad layers, so that the bonding pad region is higher than the non-bonding pad region, which is conducive to forming a height step difference between the bonding pad region and the non-bonding pad region, thereby increasing the maximum height difference between the light-emitting device 2 and the non-bonding pad region in the display panel after the light-emitting device 2 is subsequently electrically connected to the bonding pad 11, which facilities to reduce the probability of displaying dark spots caused by the black matrix covering the light-emitting device 2 when the display panel is packaged subsequently.

In a feasible implementation, as shown in FIG. 4, the display backplane further includes a heightening layer 14 located on one side of the base substrate 10 and at least partially located between the bonding pad 11 and the base substrate 10, the heightening layer 14 includes an opening 141, and part of the bonding pad 11 is located within the opening 141.

In the above implementation, on the one hand, the heightening layer 14 can further heighten the edge of the bonding pad 11, which can further increase the maximum height difference between the light-emitting device 2 and the non-bonding pad region in the display panel after the light-emitting device 2 is subsequently electrically connected to the bonding pad 11, which facilities to reduce the probability of displaying dark spots caused by the black matrix covering the light-emitting device 2 when the display panel is packaged subsequently. On the other hand, the contact area between the bonding pad 11 and the base substrate 10 can be reduced to reduce the problem of short circuit between the bonding pad 11 and the circuit inside the base substrate 10 and improve the adhesion between the bonding pad 11 and the base substrate 10.

In a feasible implementation, as shown in FIG. 4, the heightening layers 14 in the adjacent bonding pads 11 are spaced apart to form an isolation gap H, thereby improving the short circuit caused by the lateral short circuit between the adjacent bonding pads 11.

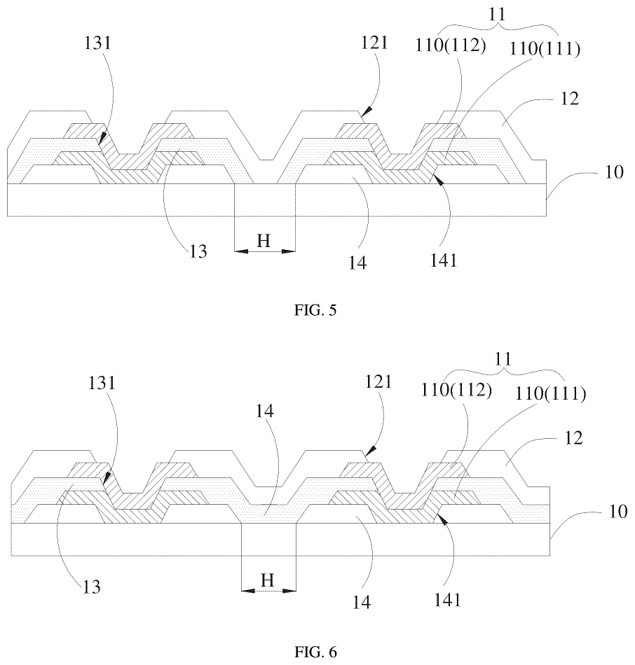

In a feasible implementation, as shown in FIG. 4 and FIG. 5, when the protective layer 12 is further included, the protective layer 12 extends between the heightening layers 14 in the adjacent bonding pads and is continuously disposed.

In the above implementation, as shown in FIG. 5 and FIG. 6, the insulating layer 13 may be formed between the adjacent heightening layers 14, and the protective layer 12 may be directly in contact with the insulating layer 13. Alternatively, as shown in FIG. 4, there may be no insulating layer 13 between the adjacent heightening layers 14, and the protective layer 12 is directly in contact with the base substrate 10.

In the above implementation, the material of the heightening layer 14 includes an organic material layer or an inorganic material layer, or the heightening layer 14 includes an organic material layer and an inorganic material layer alternately disposed in the thickness direction of the base substrate 10. Specifically, the inorganic material includes at least one of silicon nitride and silicon oxide. On the one hand, the insulation function can be realized to reduce the probability of short circuit between the bonding pad 11 and the base substrate 10, and on the other hand, the adhesion between the bonding pad 11 and the base substrate 10 can be improved.

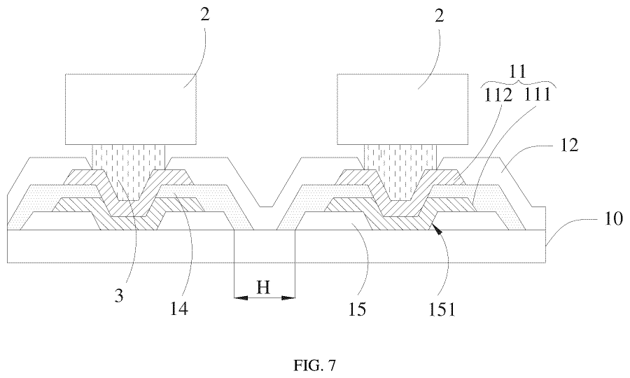

The present application further provides a display panel, as shown in FIG. 7, including the display substrate provided in the foregoing implementations of the present application.

The display panel provided in the present application further includes a light-emitting device 2 and a welding portion 3, the welding portion 3 is located inside the via 131 and electrically connected to the bonding pad 11, and the light-emitting device 2 is located on one side of the welding portion 3 away from the bonding pad 11 and electrically connected to the welding portion 3.

In the display substrate, the bonding pad 11 includes at least two bonding pad layers stacked in the thickness direction of the base substrate 10, which can increase the thickness of the bonding pad 11 in the thickness direction of the base substrate 10, increase the volume of the bonding pad 11, and increase the amount of material used in the bonding pad 11 to prevent excessive migration of metal elements from the bonding pad 11 to the welding portion 3 during the process of the electrical connection and alloying between the bonding pad 11 and the welding portion 3, thereby ensuring that sufficient metal elements still remain in the bonding pad 11, preventing the formation of a brittle layer at the connection position between the bonding pad 11 and the welding portion 3 after the metal elements migrate due to too little material used for the bonding pad 11, improving the reliability of connection between the welding portion 3 and the bonding pad 11, improving the phenomenon of separation of the two due to the formation of the brittle layer, and further improving the yield of electrical connection between the light-emitting device 2 and the display substrate to enhance the stability and reliability of the display panel. On the one hand, the insulating layer 13 plays an effect of insulation to prevent short circuit between the adjacent bonding pads 11. On the other hand, the insulating layer 13 is disposed between the adjacent bonding pad layers, the bonding pad layer on the side away from the base substrate 10 extends along the inner wall of the via 131 and is electrically connected to the bonding pad layer on the side close to the base substrate 10, so that part of the bonding pad layer on the side away from the base substrate 10 is located on one side of the insulating layer 13 away from the base substrate 10, thereby achieving the effect of heightening part of region of the bonding pad layer located on the side away from the base substrate 10 through the insulating layer 13, so that the light-emitting device 2 that is subsequently connected to the display substrate can be higher than a maximum height of a non-bonding pad region in the display panel to form a step difference, which facilities to reduce the probability of displaying dark spots caused by the black matrix covering the light-emitting device 2 when the display panel is packaged subsequently, thereby improving the display effect of the display panel. Simultaneously, the insulating layer 13 can further improve the adhesion between the adjacent bonding pad layers, improve the anti-falling property between the adjacent bonding pad layers, and increase the firmness between the adjacent bonding pad layers, so as to improve the yield of the display substrate and further improve the yield of the display panel.

When the display substrate includes the protective layer 12, the size of the welding portion 3 in the thickness direction of the base substrate 10 is greater than that of the protective layer 12 in the thickness direction of the base substrate 10, so as to improve the yield of electrical connection between the welding portion 3 and the light-emitting device 2 and enhance the stability of electrical connection.

When the display substrate includes the protective layer 12, the first opening 121 of the protective layer 12 includes a first end close to the base substrate 10 and a second end away from the base substrate 10, and the first end surrounds the welding portion 3 and is in contact with the periphery of the welding portion 3. Specifically, the first end may be in full contact with the periphery of the welding portion 3, so that the welding portion 3 and the protective layer 12 completely cover the side surface of the bonding pad 11 away from the base substrate 10 to enhance the protective effect on the bonding pad 11.

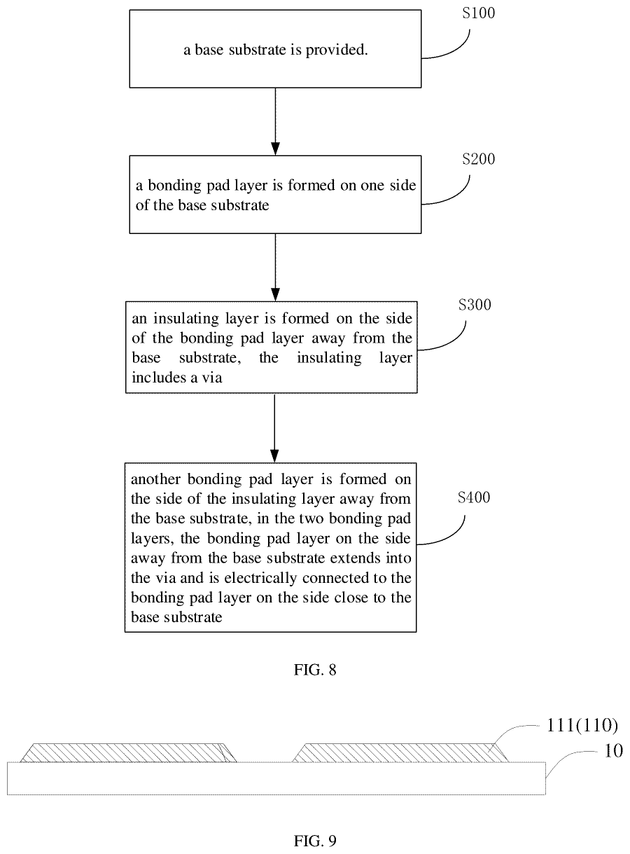

The present application further provides a method for preparing a display substrate, as shown in FIG. 8, including: S100, S200, S300 and S400.

In S100, a base substrate 10 is provided.

In S200, a bonding pad layer 110 is formed on one side of the base substrate 10.

In S300, an insulating layer 13 is formed on the side of the bonding pad layer 110 away from the base substrate 10, the insulating layer 13 includes a via 131;

In S400, another bonding pad layer 110 is formed on the side of the insulating layer 13 away from the base substrate 10, in the two bonding pad layers 110, the bonding pad layer 110 on the side away from the base substrate 10 extends into the via 131 and is electrically connected to the bonding pad layer 110 on the side close to the base substrate 10.

The above Step S200 may specifically include: S201, S202 and S203.

In S201, as shown in FIG. 9, a first bonding pad material layer is formed on one side of the base substrate 10 and patterned to form first bonding pad layers 111 arranged at intervals.

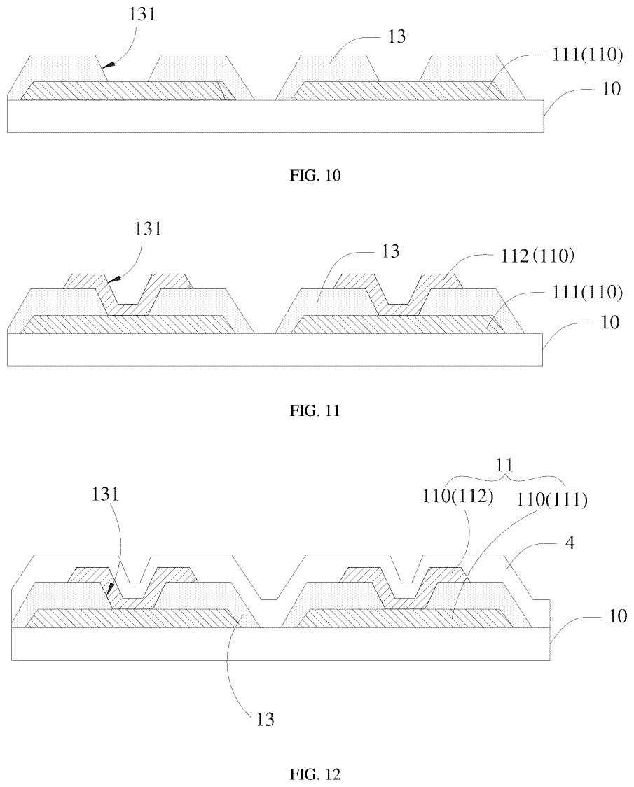

In S202, as shown in FIG. 10, an insulating material layer is formed on the side of the first bonding pad layer 111 away from the base substrate 10 and patterned to form the insulating layer 13 with the via 131, wherein the orthographic projection of the via 131 on the base substrate 10 is located within the orthographic projection of the first bonding pad layer 111 on the base substrate 10.

Specifically, the insulating material layer may include an organic material or an inorganic material, or include both an organic material and an inorganic material, and the organic material and the inorganic material are stacked.

In S203, as shown in FIG. 11, a second bonding pad material layer is formed on the side of the insulating layer 13 away from the base substrate 10 and patterned to form the second bonding pad layers 112 arranged at intervals, wherein the second bonding pad layer 112 extends into the via 131 and is electrically connected to the first bonding pad layer 111.

Specifically, the materials of the first bonding pad material layer and the second bonding pad material layer may be the same or different, preferably the same, so as to improve the difference in transmission of electrical signals by different bonding pad layers 110.

Specifically, the above only takes the example that the bonding pad 11 includes two bonding pad layers 110 for illustration. When a plurality of bonding pad layers 110 are included, steps S202 and S203 may be repeated to prepare the plurality of bonding pad layers 110 and form the insulating layer 13 between the adjacent bonding pad layers 100.

In the above implementation, the method further includes S300, S400 and S500.

In S300, as shown in FIG. 12, a protective material layer 4 is formed, wherein at least a part of the protective material layer 4 is located on the side surface of the bonding pad 11 away from the base substrate 10.

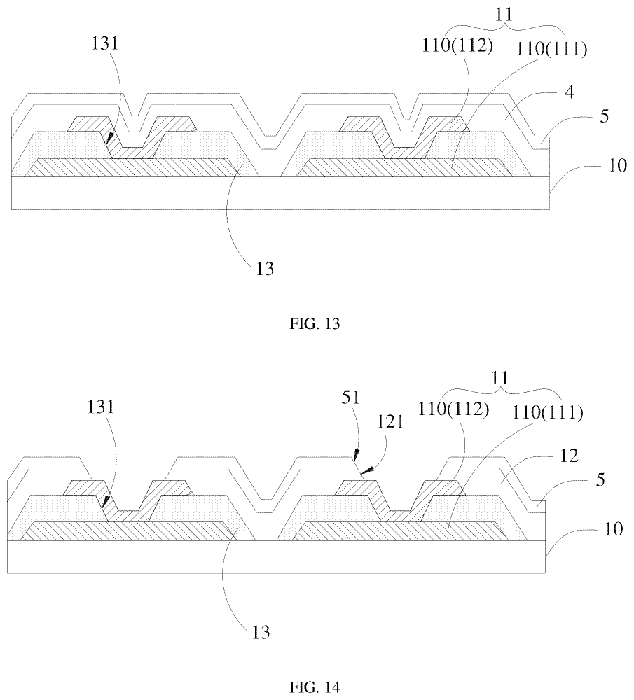

In S400, as shown in FIG. 13, a mask layer 5 is formed, wherein at least a part of the mask layer 5 is located on the side surface of a protective layer 12 away from the bonding pad 11, and the orthographic projection of the mask layer 5 on the base substrate 10 covers the base substrate 10;

In S500, as shown in FIG. 13 and FIG. 14, the protective material layer 4 and the mask layer 5 are synchronously patterned, so as to form at least one first opening 121 on the protective material layer 4 to form the protective layer 12, and to form at least one second opening 51 on the mask layer 5, wherein the second opening 51 is in communication with the first opening 121, and the orthographic projection of the first opening 121 on the base substrate 10 is located within the orthographic projection of the bonding pad 11 on the base substrate 10.

In the above preparation method, the mask layer 5 is provided as a sacrificial layer and can be synchronously patterned with the protective layer 12 to form the second opening 51 and the first opening 121, and the sizes of the two are approximate, so that when the entire welding material layer is subsequently formed on the display substrate, the mask layer 5 is removed, and only part of the welding material located in the first opening 121 and the second opening 51 is retained, thereby reducing the presence of residue on the side surface of the protective layer 12 away from the base substrate 10 after the welding material layer contacts the protective layer 12, so as to improve the preparation yield and reduce the probability of short circuit between adjacent bonding pads.

The present application further provides a method for preparing a display panel, including preparing a display substrate according to the foregoing method for preparing a display substrate, and further including: S600, S700 and S800.

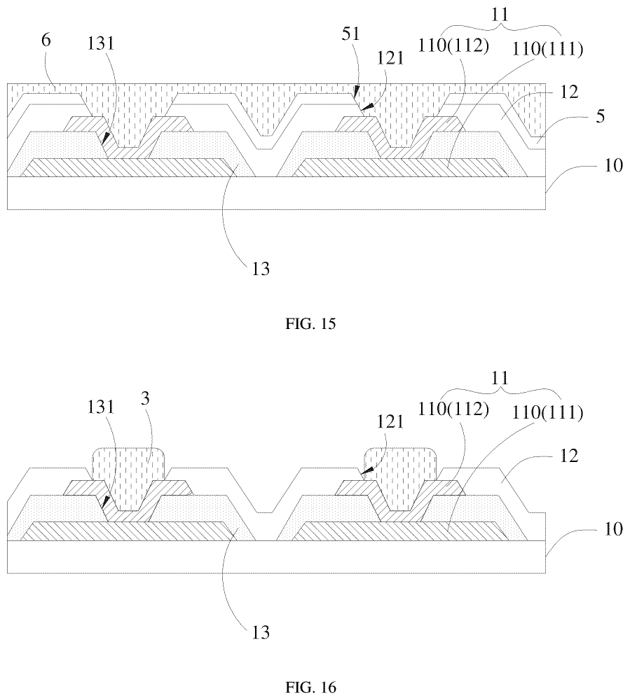

In S600, as shown in FIG. 15, a welding material layer 6 is formed on the side surface of the mask layer 5 away from the base substrate 10, and the orthographic projection of the welding material layer 6 on the base substrate 10 and the orthographic projection of the via on the base substrate 10 at least partially overlap.

In S700, as shown in FIG. 16, the mask layer 5 is removed to synchronously remove part of the welding material layer 6, the part of the welding material layer 6 located within the first opening 121 is retained, so as to form a welding portion 3, and the welding portion 3 is electrically connected to the bonding pad 11.

In S800, a light-emitting device 2 is electrically connected to the welding portion 3.

The sizes of the second opening 51 and the first opening 121 formed by preparation in steps S300-S500 are approximate, after the entire welding material layer 6 is disposed, part of the welding material layer 6 enters into the second opening 51 and the first opening 121 to form the welding portion 3. Therefore, it is convenient to achieve complete contact between the peripheral side of the welding portion 3 and the first end of the first opening 121, so that the welding portion 3 and the protective layer 12 can completely cover the side surface of the bonding pad 11 away from the base substrate 10, so as to enhance the protection effect of the bonding pad 11.

In the above implementation, the welding portion 3 is defined by the first opening 121 of the protective layer 12 and the second opening 51 of the mask layer 5 in the welding material layer 6, and then the mask layer 5 is removed, so that the size of the welding portion 3 in the thickness direction of the base substrate 10 is greater than that of the protective layer 12 in the thickness direction of the base substrate 10, which facilities to improve the yield of electrical connection between the welding portion 3 and the light-emitting device 2, and enhance the stability of electrical connection.

The present application further provides a display apparatus, including any one of the display substrates provided in the above implementations, or including any one of the display panels provided in the above implementations. The display apparatus may be a mobile terminal such as a mobile phone or a laptop, or a fixed terminal such as a television or a computer monitor, or a wearable device such as a watch, which is not specially limited by the present application.

According to the embodiments described above in the present application, these embodiments do not fully describe all details, and the present application is not limited to the specific embodiments. Apparently, many modifications and changes may be made to the above description. This specification selects and specifically describes these embodiments in order to better explain the principles and practical applications of the present application, so that those skilled in the art can make good use of the present application and modifications based on the present application. The present application is merely limited by the claims and all their scope and equivalents.

What is claimed is:

1. A display substrate, comprising:
a base substrate;
a bonding pad located on a side of the base substrate and comprising at least two bonding pad layers stacked in a thickness direction of the base substrate; and
at least one insulating layer located between adjacent two of the bonding pad layers, the insulating layer comprising a via, and in adjacent two of the bonding pad layers, the bonding pad layer on a side away from the base substrate extending into the via and being electrically connected to the bonding pad layer on a side close to the base substrate.

2. The display substrate according to claim 1, wherein the bonding pad comprises a first bonding pad layer and a second bonding pad layer stacked in the thickness direction of the base substrate, the insulating layer is located between the first bonding pad layer and the second bonding pad layer, an orthographic projection of the via on the base substrate is located within an orthographic projection of the first bonding pad layer on the base substrate, and the second bonding pad layer extends along an inner wall of the via and is electrically connected to the first bonding pad layer.

3. The display substrate according to claim 2, wherein the first bonding pad layer and the second bonding pad layer are made of a same material;
the material of the first bonding pad layer and the second bonding pad layer comprises copper, and further comprises at least one of titanium, molybdenum, and niobium.

4. The display substrate according to claim 1, wherein the insulating layer on the side close to the base substrate extends and covers a peripheral side of the bonding pad layer on the side close to the base substrate.

5. The display substrate according to claim 4, wherein the insulating layers in the adjacent bonding pads are spaced apart.

6. The display substrate according to claim 4, wherein the insulating layer extends to abut against the base substrate, and the insulating layers in the adjacent bonding pads are continuously disposed.

7. The display substrate according to claim 1, further comprising a protective layer at least partially located on a side surface of the bonding pad away from the base substrate and comprising at least one first opening, wherein an orthographic projection of the first opening on the base substrate is located within an orthographic projection of the bonding pad on the base substrate.

8. The display substrate according to claim 7, wherein the protective layer extends along the bonding pad and covers a peripheral side of the bonding pad.

9. The display substrate according to claim 8, wherein the insulating layers in the adjacent bonding pads are spaced apart, the insulating layer extends along the bonding pad layer on the side close to the base substrate and covers a peripheral side of the bonding pad layer on the side close to the base substrate, and the protective layer extends to a peripheral side of the insulating layer;
the insulating layers in the adjacent bonding pads are spaced apart, and the protective layer extends between the insulating layers in the adjacent bonding pads and abuts against the base substrate.

10. The display substrate according to claim 8, wherein the insulating layer extends to abut against the base substrate, the insulating layers in the adjacent bonding pads are continuously disposed, and the protective layer extends between the adjacent bonding pads and abuts against the insulating layer.

11. The display substrate according to claim 7, wherein a material of the protective layer comprises an inorganic material;
the inorganic material comprises at least one of silicon nitride and silicon oxide;
the protective layer has a thickness of 2 μm to 3 μm.

12. The display substrate according to claim 1, further comprising a heightening layer located on a side of the base substrate and at least partially located between the bonding pad and the base substrate, wherein the heightening layer comprises an opening, and part of the bonding pad is located within the opening.

13. The display substrate according to claim 12, wherein the heightening layers in the adjacent bonding pads are spaced apart to form an isolation gap.

14. The display substrate according to claim 12, wherein the display substrate further comprises a protective layer at least partially located on a side surface of the bonding pad away from the base substrate and comprising at least one first opening, wherein an orthographic projection of the first opening on the base substrate is located within an orthographic projection of the bonding pad on the base substrate; the protective layer extends between the heightening layers in the adjacent bonding pads and is continuously disposed.

15. A method for preparing a display substrate, comprising:
providing a base substrate;
forming a bonding pad layer on a side of the base substrate;
forming an insulating layer on a side of the bonding pad layer away from the base substrate, the insulating layer comprising a via; and
forming another bonding pad layer on a side of the insulating layer away from the base substrate, wherein in the two bonding pad layers, the bonding pad layer on a side away from the base substrate extends into the via and is electrically connected to the bonding pad layer on a side close to the base substrate.

16. The method for preparing the display substrate according to claim 15, further comprising:
forming a protective material layer, wherein at least a part of the protective material layer is located on a side surface of the bonding pad away from the base substrate;
forming a mask layer, wherein at least a part of the mask layer is located on a side surface of a protective layer away from the bonding pad, and an orthographic projection of the mask layer on the base substrate covers the base substrate; and
synchronously patterning the protective material layer and the mask layer to form at least one first opening on the protective material layer to form the protective layer, and to form at least one second opening on the mask layer, wherein the second opening is in communication with the first opening, and an orthographic projection of the first opening on the base substrate is located within an orthographic projection of the bonding pad on the base substrate.

17. A display panel, comprising:
a display substrate comprising a base substrate; a bonding pad located on a side of the base substrate and comprising at least two bonding pad layers stacked in a thickness direction of the base substrate; and at least one insulating layer located between adjacent two of the bonding pad layers, the insulating layer comprising a via, and in adjacent two of the bonding pad layers, the bonding pad layer on a side away from the base substrate extending into the via and being electrically connected to the bonding pad layer on a side close to the base substrate;
a light-emitting device, and a welding portion, wherein the welding portion is located in the via and is electrically connected to the bonding pad, and the light-emitting device is located on a side of the welding portion away from the bonding pad and is electrically connected to the welding portion.

18. The display panel according to claim 17, further comprising the protective layer at least partially located on the side surface of the bonding pad away from the base substrate and comprising at least one first opening, wherein an orthographic projection of the first opening on the base substrate is located within an orthographic projection of the bonding pad on the base substrate.

19. The display panel according to claim 18, wherein a size of the welding portion in the thickness direction of the base substrate is greater than that of the protective layer in the thickness direction of the base substrate;
the first opening comprises a first end close to the base substrate and a second end away from the base substrate, and the first end surrounds the welding portion and is in contact with a periphery of the welding portion.

20. A method for preparing a display panel, comprising:
preparing the display substrate according to the preparation method of claim 16;
forming a welding material layer located on a side surface of the mask layer away from the base substrate, wherein an orthographic projection of the welding material layer on the base substrate and an orthographic projection of the via on the base substrate at least partially overlap;
removing the mask layer to synchronously remove part of the welding material layer, retaining part of the welding material layer located within the first opening to form a welding portion, wherein the welding portion is electrically connected to the bonding pad; and
electrically connecting a light-emitting device to the welding portion.
